(19) United States
(12) Patent Application Publication
(10) Pub. No.: US 2024/0004048 A1
(43) Pub. Date: Jan. 4, 2024

(54) SEMICONDUCTOR DEVICE AND ULTRASONIC SENSOR

(71) Applicant: ROHM CO., LTD., Kyoto (JP)

(72) Inventor: Hideki MATSUBARA, Kyoto (JP)

(21) Appl. No.: 18/469,006

(22) Filed: Sep. 18, 2023

Related U.S. Application Data
(63) Continuation of application No. PCT/JP2021/046960, filed on Dec. 20, 2021.

(30) Foreign Application Priority Data
Mar. 23, 2021 (JP) 2021-048769

(51) Int. Cl. G01S 7/524; G01S 15/10

(52) U.S. Cl. CPC G01S 7/524; G01S 15/10; G01S 15/931

(57) ABSTRACT

In a semiconductor device, a drive circuit is used to supply a drive signal in an ultrasonic band to a piezoelectric element, and thereafter through a brake operation, a damping signal having a phase different from the phase of the drive signal is supplied to the piezoelectric element. The drive circuit includes a full bridge circuit provided between a first line and a second line. In the brake operation, two switches on the side of the first line in the full bridge circuit are turned on or two switches on the side of the second line in the full bridge circuit are turned on.

### CROSS-REFERENCE TO RELATED APPLICATIONS

This nonprovisional application is a continuation application of International Patent Application No. PCT/JP2021/046960 filed on Dec. 20, 2021, which claims priority Japanese Patent Application No. 2021-048769 filed on Mar. 23, 2021, the entire contents of which are hereby incorporated by reference.

### TECHNICAL FIELD

The present disclosure relates to semiconductor devices and ultrasonic sensors.

### BACKGROUND ART

Ultrasonic sensors which include piezoelectric elements are used in various applications. The ultrasonic sensor drives the piezoelectric element to transmit a transmission wave signal, and receives a reflected wave signal to perform distance detection or proximity detection of an object (see, for example, Patent document 1).

### RELATED ART DOCUMENT

### Patent Document

Patent document 1: Japanese Unexamined Patent Application Publication No. 2018-96752

### BRIEF DESCRIPTION OF DRAWINGS

FIG. 1 is an overall configuration diagram of an ultrasonic sensor according to an embodiment of the present disclosure;

FIG. 2 is a diagram showing a relationship between an output wave signal and a reflected wave signal in the ultrasonic sensor in the embodiment of the present disclosure;

FIG. 3 is a diagram showing an internal configuration of a semiconductor device of the ultrasonic sensor in the embodiment of the present disclosure;

FIG. 4 is a diagram showing a plurality of states which can be taken by a drive circuit in the embodiment of the present disclosure;

FIG. 5 is a diagram showing a relationship between an amplified voltage signal and an envelope signal based on a received signal in the embodiment of the present disclosure;

FIG. 6 is a diagram showing an example of an internal configuration of a damping circuit in the embodiment of the present disclosure;

FIG. 7 is a diagram showing how a detection unit operation is repeatedly performed by the semiconductor device in the embodiment of the present disclosure;

FIG. 8 is a diagram showing the configuration of a period during which the detection unit operation is performed in the embodiment of the present disclosure;

FIG. 9 is a diagram showing the state of each switch and the waveform of a drive signal in a transmission period in the embodiment of the present disclosure;

FIG. 10 is a diagram showing the state of each switch and the waveform of a damping signal in a first damping period in the embodiment of the present disclosure;

FIG. 11 is a diagram showing a phase relationship between the drive signal and the damping signal in the embodiment of the present disclosure;

FIG. 12 is a timing chart of the detection unit operation in a first example of the embodiment of the present disclosure;

FIG. 13 is a timing chart of the detection unit operation in a comparative example;

FIG. 14 is a diagram showing a drive circuit and its peripheral circuit in a second example of the embodiment of the present disclosure;

FIG. 15 is a timing chart of the detection unit operation in the second example of the embodiment of the present disclosure;

FIG. 16 is a variation timing chart of the detection unit operation in the second example of the embodiment of the present disclosure;

FIG. 17 is a timing chart of the detection unit operation in a third example of the embodiment of the present disclosure;

FIG. 18 is a diagram showing a drive circuit and its peripheral circuit in a fourth example of the embodiment of the present disclosure;

FIG. 19 is a timing chart of the detection unit operation in the fourth example of the embodiment of the present disclosure;

FIG. 20 is a variation timing chart of the detection unit operation in the fourth example of the embodiment of the present disclosure; and

FIG. 21 is a schematic top view of a vehicle in which a plurality of ultrasonic sensors in the embodiment of the present disclosure are installed.

### DESCRIPTION OF EMBODIMENTS

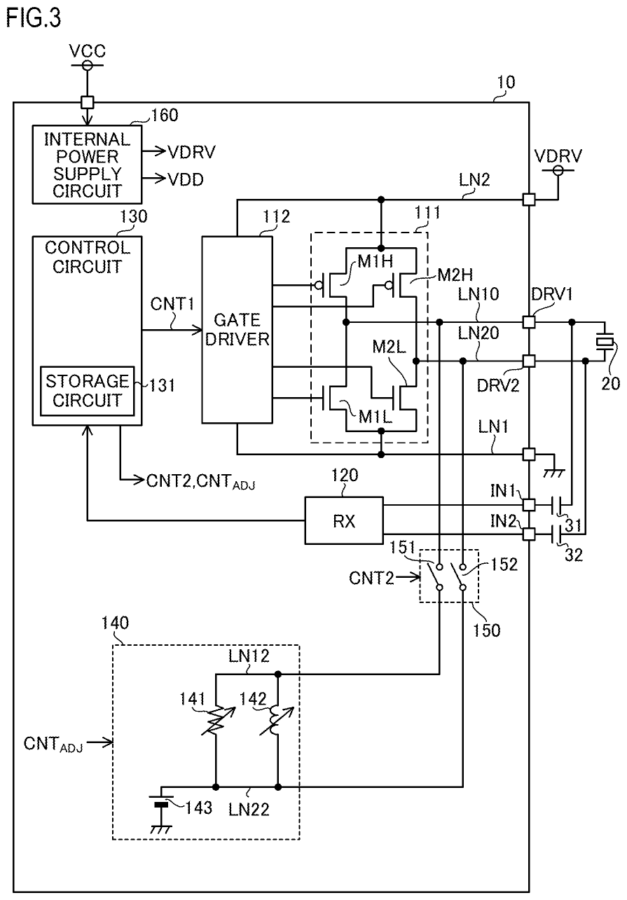

Examples of an embodiment of the present disclosure will be specifically described below with reference to drawings. In the referenced drawings, the same parts are identified with the same reference symbols, and the repeated description of the same parts is omitted in principle. In the present specification, for simplification of description, a sign or symbol indicating information, a signal, a physical quantity, an element, a part or the like is written, and thus the name of the information, the signal, the physical quantity, the element, the part or the like corresponding to the sign or symbol may be omitted or written in short. For example, although a damping circuit described later which is represented by “140” (see FIG. 3) may be written as the damping circuit 140 or may be written in short as the circuit 140, all of them represent the same thing.

A description will first be given of some terms used in the description of the embodiment of the present disclosure. Lines refer to wiring through which electrical signals are propagated or applied. A ground refers to a reference conductive portion having a potential of 0 V (zero volt) as a reference or refers to a potential of 0 V itself. The reference conductive portion is formed of a conductor such as metal. A potential of 0 V may be referred to as a ground potential. In the embodiment of the present disclosure, a voltage shown without provision of a specific reference indicates a potential relative to the ground.

For any transistor configured as an FET (Field Effect Transistor) including a MOSFET, an on state refers to a state in which there is continuity between the drain and the source of the transistor, and an off state refers to a state (interrupted state) in which there is no continuity between the drain and the source of the transistor. The same is true for transistors which are not classified as FETs. MOSFETs are interpreted to be enhancement-type MOSFETs unless otherwise stated. The MOSFET is an abbreviation for “metal-oxide-semiconductor field-effect transistor”.

An arbitrary switch can be formed with one or more FETs (Field Effect Transistors), and when a certain switch is in the on state, both ends of the switch are electrically continuous whereas when a certain switch is in the off state, both ends of the switch are not electrically continuous. In the following description, the on state and the off state of an arbitrary transistor or switch may be simply expressed as on and off. Connections between a plurality of parts forming a circuit such as an arbitrary circuit element, wiring (line) and a node may be interpreted to refer to electrical connections unless otherwise specified.

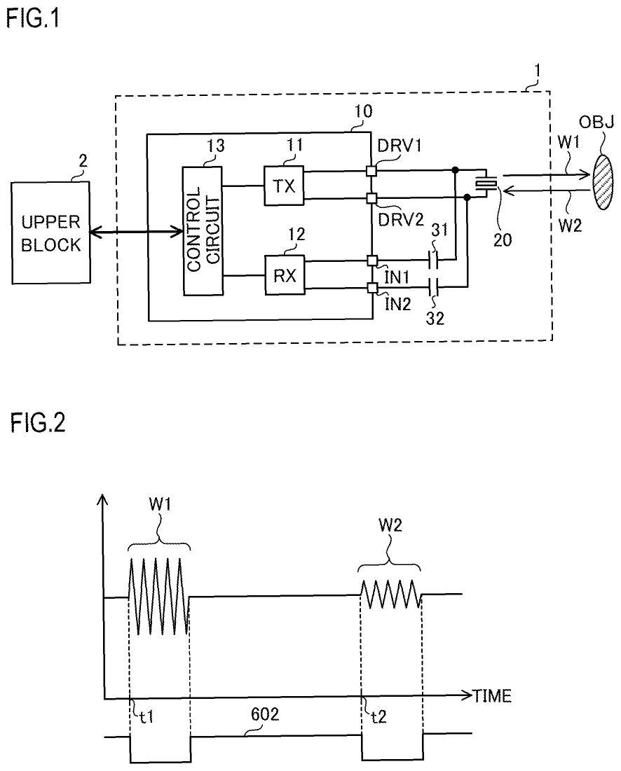

FIG. 1 shows an overall configuration of an ultrasonic sensor 1 according to an embodiment of the present disclosure. FIG. 1 also shows an upper block 2 which is connected to the ultrasonic sensor 1 and an object to be detected OBJ which is present in a position physically separated from the ultrasonic sensor 1. The ultrasonic sensor 1 includes a semiconductor device 10 which is formed with a semiconductor integrated circuit for an ultrasonic sensor, a piezoelectric element 20 and capacitors 31 and 32. In FIG. 1, only a part of the internal configuration of the semiconductor device 10 is shown.

The ultrasonic sensor 1 transmits an output wave signal W1 in an ultrasonic band toward an external space of the ultrasonic sensor 1 (in a direction away from the ultrasonic sensor 1). The output wave signal W1 is reflected off the object to be detected OBJ to generate a reflected wave signal W2. The reflected wave signal W2 is received by the ultrasonic sensor 1. Based on the received signal of the reflected wave signal W2, the ultrasonic sensor 1 performs the detection of a distance to the object to be detected OBJ, the proximity detection of the object to be detected OBJ and the like. The ultrasonic band refers to a frequency band which is higher than the band of sound waves audible to the human ear and is inaudible to the human ear, and generally refers to a band of 20 kHz or more. For example, the output wave signal W1 has a frequency in a range of 30 kHz to 80 kHz. Both the output wave signal W1 and the reflected wave signal W2 belong to ultrasonic signals.

The piezoelectric element 20 includes a first end and a second end. The piezoelectric element 20 generates a mechanical displacement (vibration) in itself in response to a voltage signal applied between the first end and the second end, and generates the output wave signal W1 by its own mechanical displacement. Hence, the piezoelectric element 20 functions as a transmitter for the output wave signal W1. The piezoelectric element 20 has the property of generating an electromotive force between the first end and the second end in response to a mechanical displacement (vibration) applied to itself, and also functions as a receiver for the reflected wave signal W2.

The semiconductor device 10 uses the piezoelectric element 20 to perform an operation of transmitting the output wave signal W1 and an operation of receiving the reflected wave signal W2. In the following description, a combination of the operation of transmitting the output wave signal W1 and the operation of receiving the reflected wave signal W2 may be referred to as a transmission/reception operation. The semiconductor device 10 includes a transmission circuit 11, a reception circuit 12 and a control circuit 13. The semiconductor device 10 is an electronic component formed by enclosing a semiconductor integrated circuit in a housing (package) made of resin, and each of the circuits which constitute the semiconductor device 10 is integrated by a semiconductor. In the housing of the electronic component serving as the semiconductor device 10, a plurality of external terminals are provided which are exposed from the housing to the outside of the semiconductor device 10. As a part of the external terminals provided in the semiconductor device 10, output terminals DRV1 and DRV2 and input terminals IN1 and IN2 are shown in FIG. 1. Outside the semiconductor device 10, the output terminal DRV1 is connected to the first end of the piezoelectric element 20, and the output terminal DRV2 is connected to the second end of the piezoelectric element 20. Outside the semiconductor device 10, the input terminal IN1 is connected via the capacitor 31 to the first end of the piezoelectric element 20, and the input terminal IN2 is connected via the capacitor 32 to the second end of the piezoelectric element 20. The capacitors 31 and 32 may be incorporated in the semiconductor device 10.

The transmission circuit 11 uses the piezoelectric element 20 externally connected between the output terminals DRV1 and DRV2 to transmit the output wave signal W1. The reception circuit 12 uses the piezoelectric element 20 externally connected between the input terminals IN1 and IN2 to receive an input wave signal in the ultrasonic band. A main input wave signal which is to be received is the reflected wave signal W2 based on the output wave signal W1. As described above, in the present embodiment, the common piezoelectric element 20 is externally connected between the output terminals DRV1 and DRV2 and between the input terminals IN1 and IN2, and the common piezoelectric element 20 is shared by the transmission circuit 11 and the reception circuit 12 as a transducer.

However, as a variation, between the input terminals IN1 and IN2, another piezoelectric element (not shown) which is different from the piezoelectric element 20 may be externally connected (in this case, the other piezoelectric element described above is also included in the constituent elements of the ultrasonic sensor 1). Alternatively, when the common piezoelectric element 20 is shared by the transmission circuit 11 and the reception circuit 12, the output terminal DRV1 and the input terminal IN1 may be realized by one first input/output terminal, and the output terminal DRV2 and the input terminal IN2 may be realized by one second input/output terminal and the first and second input/output terminals may be connected in parallel to both the transmission circuit 11 and the reception circuit 12 (in this case, the capacitors 31 and 32 may be inserted between the first and second input/output terminals and the reception circuit 12). The reception circuit 12 uses the piezoelectric element 20 or the other piezoelectric element described above to receive the input wave signal in the ultrasonic band, and performs predetermined reception signal processing on the received signal.

The control circuit 13 controls the transmission circuit 11 and the reception circuit 12. The control circuit 13 controls and uses the transmission circuit 11 to cause the piezoelectric element 20 to transmit the output wave signal W1. The control circuit 13 performs the detection of the distance to the object to be detected OBJ, the proximity detection of the object to be detected OBJ and the like based on the signal received by the reception circuit 12 (the input wave signal received by the reception circuit 12).

FIG. 2 is a diagram showing the transmission/reception operation performed by the ultrasonic sensor 1. The control circuit 13 can perform distance detection processing and the proximity detection processing. In the distance detection processing, the control circuit 13 measures the length of a time (that is, the length between time t1 and time t2) after the output wave signal W1 is transmitted at time t1 until the reflected wave signal W2 is received at time t2, and thereby calculates the distance between the ultrasonic sensor 1 and the object to be detected OBJ. Time t1 indicates a time at which the transmission of the output wave signal W1 using the transmission circuit 11 and the piezoelectric element 20 is started, and time t2 indicates a time at which the reception of the reflected wave signal W2 using the reception circuit 12 and the piezoelectric element 20 is started. In the proximity detection processing, the control circuit 13 performs the proximity detection of the object to be detected OBJ based on whether or not the reflected wave signal W2 is received. More specifically, for example, when in the proximity detection processing, the control circuit 13 receives the reflected wave signal W2 after the output wave signal W1 is transmitted at time t1 until a predetermined time elapses, the control circuit 13 determines that the object to be detected OBJ approaches the ultrasonic sensor 1 (for example, a vehicle in which the ultrasonic sensor 1 is installed) whereas when this is not the case, the control circuit 13 determines that the object to be detected OBJ does not approach the ultrasonic sensor 1 (for example, the vehicle in which the ultrasonic sensor 1 is installed).

The control circuit 13 is connected to the upper block 2 shown in FIG. 1 to be able to perform two-way communication therewith. The upper block 2 transmits predetermined commands to the semiconductor device 10 to be able to provide various instructions to the semiconductor device 10, and the semiconductor device 10 performs various types of operations and processing corresponding to the commands received from the upper block 2. The results of the distance detection processing and the proximity detection processing are transmitted from the semiconductor device 10 to the upper block 2. The upper block 2 is formed with a microcomputer or the like. When the ultrasonic sensor 1 and the upper block 2 are installed in a vehicle such as an automobile, the upper block 2 may be an ECU (Electronic Control Unit). The measurement of the length between time t1 and time t2, the calculation of the distance between the ultrasonic sensor 1 and the object to be detected OBJ based on the result of the measurement and the determination as to whether or not the object to be detected OBJ approaches the ultrasonic sensor 1 (for example, the vehicle in which the ultrasonic sensor 1 is installed) may be performed in the upper block 2. In this case, for example, a signal, such as a signal 602 in FIG. 2, that indicates a period during which the output wave signal W1 is transmitted and a period during which the reflected wave signal W2 is received is preferably transmitted from the control circuit 13 to the upper block 2.

FIG. 3 shows an internal configuration diagram of the semiconductor device 10. The semiconductor device 10 includes a drive circuit 111, a gate driver 112, a reception circuit 120 and a control circuit 130. The transmission circuit 11 in FIG. 1 is formed by the drive circuit 111 and the gate driver 112. The reception circuit 120 corresponds to the reception circuit 12 in FIG. 1, and has the function of the reception circuit 12 described above. The control circuit 130 corresponds to the control circuit 13 in FIG. 1, and has the function of the control circuit 13 described above. The semiconductor device 10 further includes a damping circuit 140, a switch circuit 150 and an internal power supply circuit 160.

The drive circuit 111 includes transistors M1H, M1L, M2H and M2L as four switching elements (switches). The transistors M1H and M2H are p-channel MOSFETs, and the transistors M1L and M2L are n-channel MOSFETs. The transistors M1H and M1L are connected in series to form a first half bridge circuit (first series circuit), and the transistors M2H and M2L are connected in series to form a second half bridge circuit (second series circuit). A full bridge circuit (H bridge circuit) is formed by the first and second half bridge circuits. The sources of the transistors M1H and M2H are connected to a line LN2. A drive power supply voltage VDRV which has a predetermined positive direct-current voltage value is applied to the line LN2. The drains of the transistors M1H and M1L are commonly connected to a line LN10, and are connected to the output terminal DRV1 through the line LN10. The drains of the transistors M2H and M2L are commonly connected to a line LN20, and are connected to the output terminal DRV2 through the line LN20. The sources of the transistors M1L and M2L are connected to a line LN1. A ground potential is applied to the line LN1. As described above, the output terminal DRV1 and the input terminal IN1 are connected to the first end of the piezoelectric element 20 outside the semiconductor device 10, and the output terminal DRV2 and the input terminal IN2 are connected to the second end of the piezoelectric element 20 outside the semiconductor device 10 (however, the input terminals IN1 and IN2 are connected to the first end and the second end of the piezoelectric element 20 via the capacitors 31 and 32). As a variation, the transistors M1H and M2H can be formed with n-channel MOSFETs (in this case, a circuit which generates a voltage higher than the drive power supply voltage VDRV is added).

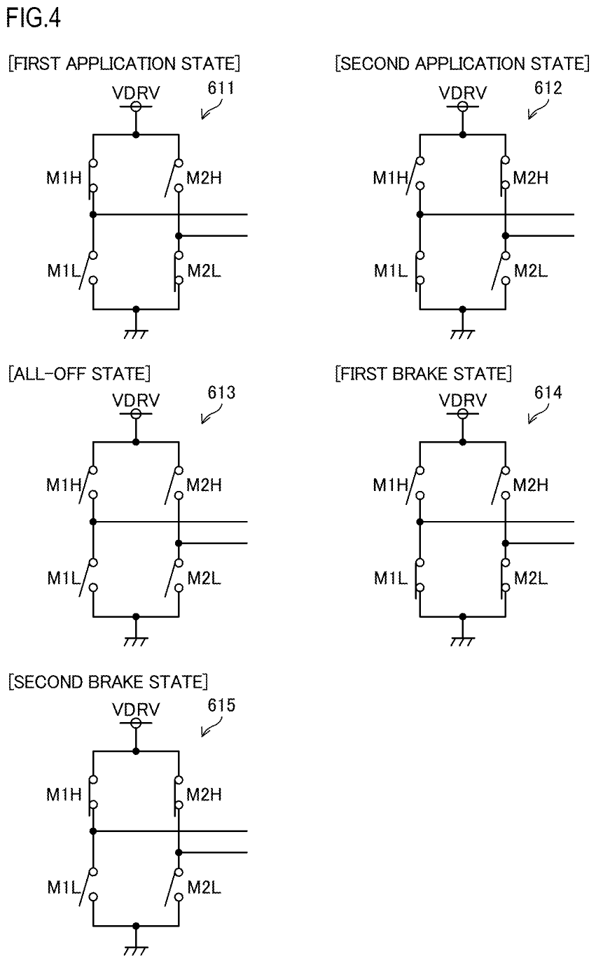

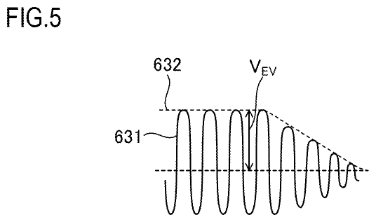

The gate driver 112 is driven using the drive power supply voltage VDRV applied to the line LN2 as a positive power supply voltage and a ground voltage (0 V) applied to the line LN1 as a negative power supply voltage. The gate driver 112 controls the gate potentials of the transistors M1H, M1L, M2H and M2L according to the control signal CNT1 supplied from the control circuit 130, and thereby individually controls the on/off states of the transistors M1H, M1L, M2H and M2L. By controlling the gate potentials of the transistors M1H, M1L, M2H and M2L, the state of the drive circuit 111 can be set to any one of states 611 to 615 in FIG. 4. The drive circuit 111 may have a state which is different from the states 611 to 615.

The state 611 is a first application state. In the first application state, the transistors M1H and M2L are on, and the transistors M2H and M1L are off. The state 612 is a second application state. In the second application state, the transistors M1L and M2H are on, and the transistors M1H and M2L are off. The state 613 is an all-off state. In the all-off state, all the transistors M1H, M1L, M2H and M2L are off. The state 614 is a first brake state. In the first brake state, the transistors M1L and M2L are on, and the transistors M1H and M2H are off. The state 615 is a second brake state. In the second brake state, the transistors M1L and M2L are off, and the transistors M1H and M2H are on.

The reception circuit 120 is connected to the input terminals IN1 and IN2, and receives a voltage signal applied between the input terminals IN1 and IN2. Hence, when the piezoelectric element 20 receives the reflected wave signal W2, based on the reflected wave signal W2, a voltage signal generated between the first end and the second end of the piezoelectric element 20 is input through the input terminals IN1 and IN2 to the reception circuit 120. The reception circuit 120 performs predetermined reception signal processing on the voltage signal between the input terminals IN1 and IN2 to generate a detection signal based on the voltage signal between the input terminals IN1 and IN2. The reception signal processing includes: direct-current removal processing for removing a direct-current component from the voltage signal between the input terminals IN1 and IN2; amplification processing for amplifying the voltage signal after the direct-current removal processing; envelope detection processing for detecting an envelope of the voltage signal after the amplification processing (hereinafter referred to as an amplified voltage signal); and the like. The detection signal generated in the reception circuit 120 includes an envelope signal. However, when as shown in FIG. 3, the capacitors 31 and 32 are provided between the input terminals IN1 and IN2 and the piezoelectric element 20, the direct-current removal processing in the stage of the reception signal processing can be omitted. In FIG. 5, a solid-line waveform 631 is the waveform of the amplified voltage signal, and a dashed-line waveform 632 is the waveform of an envelope signal. The envelope signal is a voltage signal which has the magnitude of the amplitude of the amplified voltage signal as a voltage value. Hence, the envelope signal has a voltage value (hereinafter referred to as a voltage value V_{EV}) which is proportional to the amplitude of the received signal of the reception circuit 120 (that is, the voltage signal between the input terminals IN1 and IN2).

The control circuit 130 performs the distance detection processing and the proximity detection processing described above based on the detection signal generated in the reception circuit 120, and also performs overall control of the operations of units within the semiconductor device 10. In this control, the control circuit 130 generates and outputs control signals CNT1, CNT2 and CNT_{ADJ}. The control circuit 130 includes a storage circuit 131. In the storage circuit 131, a non-volatile memory and a volatile memory are provided. The non-volatile memory in the storage circuit 131 includes a memory (One Time Programmable ROM) in which data can be written only once or a memory in which data can be rewritten. The volatile memory in the storage circuit 131 includes a register.

The damping circuit 140 includes a resistive component 141, an inductive component 142 and a bias supply circuit 143. The resistive component 141 and the inductive component 142 are elements which are utilized to reduce the reverberation of the piezoelectric element 20, and function as loads of the piezoelectric element 20. Hence, the resistive component 141 and the inductive component 142 are hereinafter referred to as the resistive load 141 and the inductive load 142, respectively. The resistive load 141 and the inductive load 142 are connected in parallel with each other, and the parallel circuit of the resistive load 141 and the inductive load 142 is connected between the lines LN12 and LN22. The bias supply circuit 143 supplies a predetermined direct-current bias voltage (for example, 2 V) to the line LN22. The resistive load 141 is formed such that the resistance value of the resistive load 141 is variable, and the inductive load 142 is formed such that the inductance value of the inductive load 142 is variable. The resistance value of the resistive load 141 and the inductance value of the inductive load 142 are variably set according to the control signal CNT_{ADJ} from the control circuit 130.

The switch circuit 150 includes switches 151 and 152. Each of the switches in the switch circuit 150 can be formed with one or more MOSFETs. Each of the switches in the switch circuit 150 may be a bus switch which can propagate an analogue signal. The first end of the switch 151 is connected to the line LN10, and the second end of the switch 151 is connected to a line LN12. The first end of the switch 152 is connected to the line LN20, and the second end of the switch 152 is connected to a line LN22. The switches 151 and 152 are controlled based on the control signal CNT2 supplied from the control circuit 130 so as to be turned on or off. The control signal CNT2 is a binary signal having a value of “0” or “1”. When the control signal CNT2 has a value of “1”, both the switches 151 and 152 are turned on whereas when the control signal CNT2 has a value of “0”, both the switches 151 and 152 are turned off.

Based on a power supply voltage VCC supplied from an unillustrated external power supply device to the semiconductor device 10, the internal power supply circuit 160 generates a plurality of power supply voltages including the drive power supply voltage VDRV and an internal power supply voltage VDD. Each circuit within the semiconductor device 10 is driven based on any one of the power supply voltages generated in the internal power supply circuit 160. For example, the control circuit 130 and the damping circuit 140 may be driven based on the internal power supply voltage VDD. Although here, both the drive power supply voltage VDRV and the internal power supply voltage VDD have a positive direct-current voltage value, the internal power supply voltage VDD is lower than the drive power supply voltage VDRV. For example, the drive power supply voltage VDRV is 36 V or 72 V whereas the internal power supply voltage VDD is 3 V or 5 V.

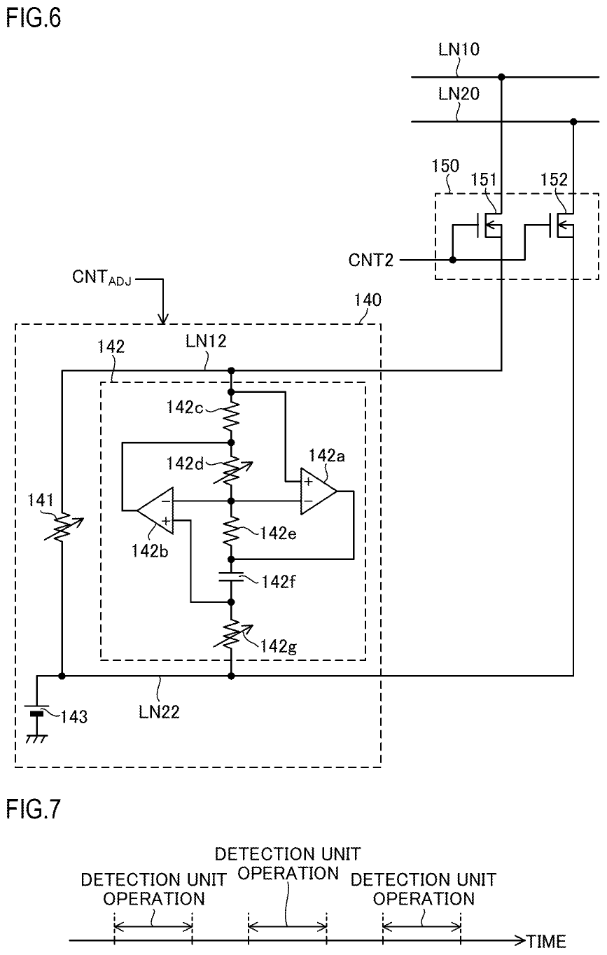

FIG. 6 shows a specific example of the configuration of the damping circuit 140. The inductive load 142 is formed with a pseudo inductor such that the inductance value of the inductive load 142 within the semiconductor device 10 can be arbitrarily changed. In FIG. 6, the inductive load 142 is formed with a GIC (Generalized Impedance Converter) circuit. Specifically, the inductive load 142 in FIG. 6 includes operational amplifiers 142a and 142b, fixed resistors 142c and 142e, variable resistors 142d and 142g and a capacitor 142f. Each of the fixed resistors 142c and 142e has a fixed resistance value. By contrast, as with the resistance value of the resistive load 141, the resistance values of the variable resistors 142d and 142g can be independently changed according to the control signal CNT_{ADJ} from the control circuit 130. The resistance values of the variable resistors 142d and 142g are changed, and thus the inductance value of the inductive load 142 connected between the lines LN12 and LN22 is changed.

The first end of the fixed resistor 142c is commonly connected to the line LN12 and the non-inverting input terminal of the operational amplifier 142a. The second end of the resistor 142c is commonly connected to the first end of the variable resistor 142d and the output terminal of the operational amplifier 142b. The second end of the variable resistor 142d is commonly connected to the inverting input terminals of the operational amplifiers 142a and 142b and the first end of the fixed resistor 142e. The second end of the fixed resistor 142e is commonly connected to the output terminal of the operational amplifier 142a and the first end of the capacitor 142f. The second end of the capacitor 142f is commonly connected to the first end of the variable resistor 142g and the non-inverting input terminal of the operational amplifier 142b. The second end of the variable resistor 142g is connected to the line LN22. The power supply voltages of the operational amplifiers 142a and 142b are determined such that the GIC circuit functions as an inductive load for the piezoelectric element 20 in a period during which the switches 151 and 152 are on.

As shown in FIG. 6, each of the switches 151 and 152 can be formed with an n-channel MOSFET. In this case, in the MOSFET serving as the switch 151, the drain is connected to the line LN10 whereas the source is connected to the line LN12, and in the MOSFET serving as the switch 152, the drain is connected to the line LN20 whereas the source is connected to the line LN22. The common control signal CNT2 is input to the gates of the MOSFETs serving as the switches 151 and 152, and thus the switches 151 and 152 are turned on or off. The configuration of the switches 151 and 152 is not limited to the configuration shown in FIG. 6, and may be arbitrarily selected.

With reference to FIG. 7, in the semiconductor device 10, one or more detection unit operations can be performed under the control of the control circuit 130 in response to the command from the upper block 2. In each of the detection unit operations, the distance detection processing and the proximity detection processing are performed. FIG. 7 shows how a plurality of detection unit operations are performed sequentially and repeatedly.

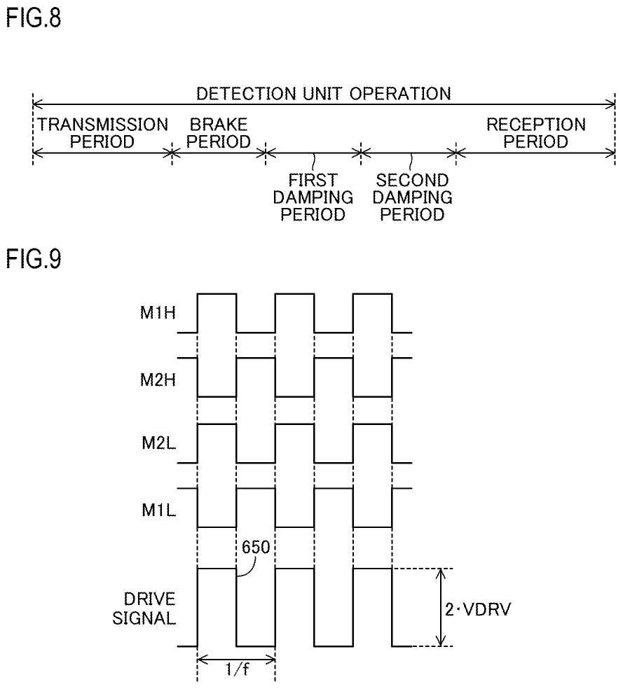

A period during which each detection unit operation is performed is referred to as a detection unit period. As shown in FIG. 8, each detection unit period is roughly divided into a transmission period, a brake period, a first damping period, a second damping period and a reception period. In each detection unit period, the transmission period, the brake period, the first damping period, the second damping period and the reception period come in this order. The first damping period can also be referred to as a damping pulse period, and the second damping period can also be referred to as a damping period.

The transmission period is a period during which the output wave signal W1 is transmitted. FIG. 9 shows the state of each switch within the drive circuit 111 in the transmission period and the waveform 650 of the drive signal supplied from the drive circuit 111 to the piezoelectric element 20 in the transmission period. Under the control of the control circuit 130, the state of the drive circuit 111 is alternately and periodically switched between the first application state and the second application state in the transmission period. The drive signal corresponds to a voltage signal applied between the output terminals DRV1 and DRV2 in the transmission period, and is assumed here to be a voltage signal which has the potential of the output terminal DRV1 with respect to the potential of the output terminal DRV2. Hence, in the transmission period, the drive signal is a rectangular wave signal having a frequency f, and a voltage difference between the minimum value and the maximum value of the drive signal is twice the drive power supply voltage VDRV.

Even after the supply of the drive signal is stopped through the supply of the drive signal to the piezoelectric element 20, the piezoelectric element 20 continues to vibrate for a while based on mechanical energy accumulated by itself in the transmission period. Vibration of the piezoelectric element 20 after the supply of the drive signal is stopped is called reverberation. The duration of reverberation is called a reverberation time. When the reverberation time is long, for example, it is difficult to detect an object in close range. After the supply of the drive signal to the piezoelectric element 20 is stopped, a signal having a phase opposite to that of the drive signal is supplied to the piezoelectric element 20, and thus the reverberation time can be reduced. In the present embodiment, after the supply of the drive signal to the piezoelectric element 20 is stopped, a signal having a phase different from that of the drive signal is supplied as the damping signal from the drive circuit 111 to the piezoelectric element 20, and thus the reverberation time is reduced. The first damping period (see FIG. 8) corresponds to a period during which the damping signal is supplied to the piezoelectric element 20.

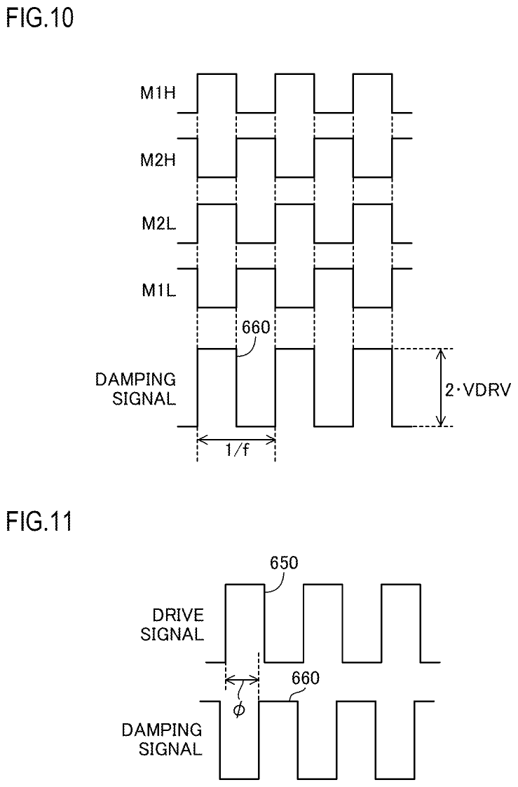

FIG. 10 shows the state of each switch within the drive circuit 111 in the first damping period and the waveform 660 of the damping signal supplied from the drive circuit 111 to the piezoelectric element 20 in the first damping period. Under the control of the control circuit 130, the state of the drive circuit 111 is alternately and periodically switched between the first application state and the second application state in the first damping period. The damping signal corresponds to a voltage signal applied between the output terminals DRV1 and DRV2 in the first damping period, and is assumed here to be a voltage signal which has the potential of the output terminal DRV1 with respect to the potential of the output terminal DRV2. Hence, in the first damping period, the damping signal is a rectangular wave signal having a frequency f, and a voltage difference between the minimum value and the maximum value of the damping signal is twice the drive power supply voltage VDRV. The frequency f of the damping signal is the same as the frequency f of the drive signal.

FIG. 11 shows the waveforms 650 and 660 of the drive signal and the damping signal. Although the drive signal and the damping signal are not supplied to the piezoelectric element 20 at the same time, the waveforms 650 and 660 of the drive signal and the damping signal are shown side by side in an up/down direction in FIG. 11 for convenience so that the relationship thereof is shown. The phase of the damping signal relative to the phase of the drive signal is represented by a symbol “ϕ”. Here, it is considered that the damping signal is delayed in phase relative to the drive signal, and the amount of phase delay of the damping signal relative to the drive signal is assumed to be the phase ϕ.

The phase ϕ preferably has 180° or a value (angle) close thereto. Based on the data and the like stored in the storage circuit 131, each detection unit operation is performed in a state where the phase ϕ, the resistance value of the resistive load 141 and the inductance value of the inductive load 142 are appropriately set.

The damping signal may also be called a damping pulse signal. Although the damping pulse signal is effective for reducing the reverberation in a region where the amplitude of the reverberation (the amplitude of the piezoelectric element 20 caused by the reverberation) is high, as the amplitude of the reverberation is lowered, the damping pulse signal itself may serve as a factor for new reverberation. On the other hand, the resistive load or the inductive load is connected to the piezoelectric element 20 after the supply of the drive signal is stopped, thus the reverberation is reduced through the absorption of the mechanical energy of the piezoelectric element 20. Here, the inventor has found this time that the resistive load or the inductive load has a relatively high reverberation reduction effect when the amplitude of the reverberation is small whereas the reverberation reduction effect is relatively low when the amplitude of the reverberation is large due to a voltage restriction for the circuit or the like.

Based on the findings described above, the inventor has developed the following reverberation reduction operation. In the reverberation reduction operation, after the supply of the drive signal to the piezoelectric element 20 is stopped, the damping signal is supplied by the drive circuit 111 to the piezoelectric element 20, and after the supply of the damping signal is stopped, the damping circuit 140 is connected to the piezoelectric element 20. By the reverberation reduction operation as described above, it is possible to rapidly reduce the reverberation (that is, the reverberation time can be kept low).

In all or a part of the second damping period (the damping period; see FIG. 8), the damping circuit 140 is connected to the piezoelectric element 20. Thereafter, in the reception period, a reception operation is performed by the reception circuit 120. Specifically, the reception circuit 120 performs the predetermined reception signal processing on the voltage signal between the input terminals IN1 and IN2 in the reception period, and thereby generates the detection signal based on the voltage signal between the input terminals IN1 and IN2 in the reception period. The control circuit 130 performs the distance detection processing and the proximity detection processing described above based on the detection signal generated in the reception circuit 120.

As shown in FIG. 8, between the transmission period and the first damping period, the brake period is set. The phase ϕ of the damping signal is determined by the length of the brake period. For example, if the length of the brake period is “1/(2f)” (that is, if the length of the brake period is half the reciprocal of the frequency f described above) or if the length of the brake period is “m/f+1/(2f)”, then the phase ϕ is 1800 (where m is any natural number). As specific control, the control circuit 130 sets the state of the drive circuit 111 to the first brake state or the second brake state in all or part of the brake period (see FIG. 4). The operation of setting the state of the drive circuit 111 to the first brake state or the second brake state (that is, the operation of keeping the state of the drive circuit 111 in the first brake state or the second brake state) is referred to as the brake operation.

Hereinafter, in a plurality of examples, some specific operation examples, application techniques, variation techniques and the like related to the ultrasonic sensor 1 will be described. The matters described above in the present embodiment are applied to each of the following examples unless otherwise stated and as long as there is no contradiction. If there is a contradiction for the matters described above in each of the examples, the description in the example may take precedence. As long as there is no contradiction, among a plurality of examples described below, matters described in an arbitrarily example can also be applied to any other example (that is, two or more examples in the plurality of examples can be combined together).

### First Example

A first example will be described. In the first example, in the brake operation, the drive circuit 111 is set and held in the first brake state (see FIG. 4).

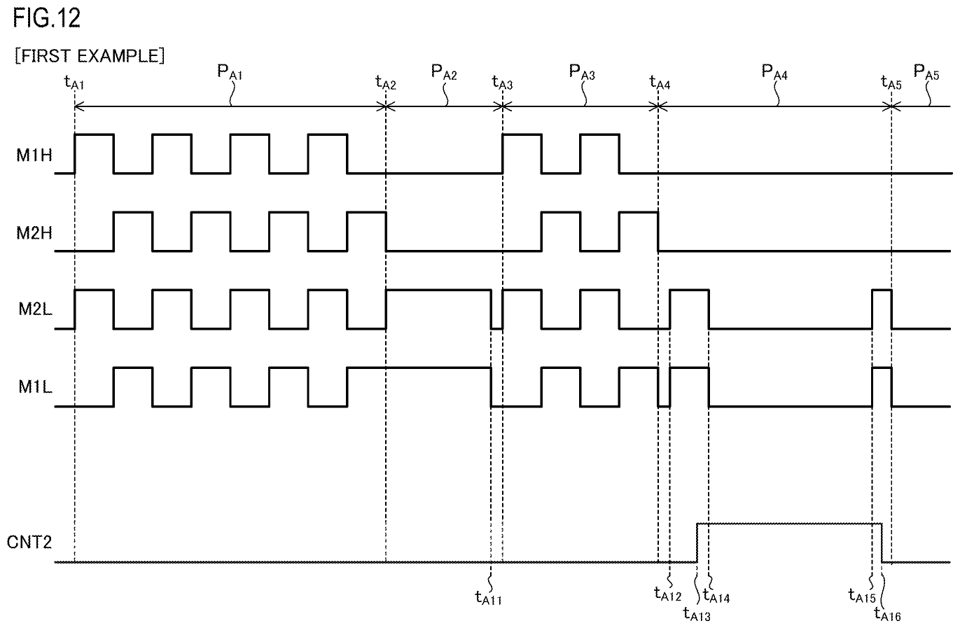

FIG. 12 shows a timing chart of the detection unit operation in the first example. It is assumed that time t_{A1}, time t_{A2}, time t_{A3}, time t_{A4} and time t_{A5} come in this order over time. Periods P_{A1}, P_{A2}, P_{A3}, P_{A4} and P_{A5} in FIG. 12 are examples of the transmission period, the brake period, the first damping period, the second damping period and the reception period, respectively. An operation in each of the periods will be specifically described below.

The period from time t_{A1} to time t_{A2} is the transmission period P_{A1} during which the drive signal is supplied from the drive circuit 111 to the piezoelectric element 20. In the transmission period P_{A1}, the drive signals corresponding to the number of waves transmitted are supplied to the piezoelectric element 20. The number of waves transmitted in the transmission period P_{A1} corresponds to the number of cycles of the drive signal in the transmission period P_{A1} (that is, a quotient obtained by dividing the length of the transmission period P_{A1} by the length of the period of the drive signal). The number of waves transmitted in the transmission period P_{A1} is a predetermined value (for example, an integer of 2 or more), and is set based on data within a predetermined register in the storage circuit 131. Although it is assumed here that the number of waves transmitted is “4”, the number of waves transmitted is not limited (the same is true in the other examples described later). When a length (4/f) corresponding to the four periods of the drive signal has elapsed since time t_{A1} (that is, at time t_{A2}), the transmission period P_{A1} is completed.

Before time t_{A1}, the drive circuit 111 is kept in an initial state for a fixed time, and the drive circuit 111 is switched from the initial state to the first application state at time t_{A1}, with the result that the supply of the drive signal to the piezoelectric element 20 is started (the same is true in the other examples described later). Although in the example of FIG. 12, the all-off state is assumed to be the initial state, the initial state may be any one of the all-off state, the second application state, the first brake state and the second brake state (the same is true in the other examples described later).

The period from time t_{A2} to time t_{A3} is the brake period P_{A2}. In the first example, in all or a part of the brake period P_{A2}, the drive circuit 111 is kept in the first brake state (that is, the transistors M1H and M2H are kept off, and the transistors M1L and M2L are kept on). In the example of FIG. 12, time t_{A11} is present between time t_{A2} and time t_{A3}, the drive circuit 111 is kept in the first brake state from time t_{A2} to time t_{A11} and the drive circuit 111 is kept in the all-off state from time t_{A11} to time t_{A3}. However, a variation can also be adopted in which the drive circuit 111 is kept in the first brake state in the entire period from time t_{A2} to time t_{A3}. Another variation can also be adopted in which the drive circuit 111 is kept in the all-off state until a predetermined minute time has elapsed since time t_{A2}, and the drive circuit 111 is kept in the first brake state until time t_{A11} or time t_{A3} after the predetermined minute time has elapsed since time t_{A2}.

The period from time t_{A3} to time t_{A4} is the first damping period P_{A3} during which the damping signal is supplied from the drive circuit 111 to the piezoelectric element 20. In the first damping period P_{A3}, the damping signals corresponding to the number of damping waves are supplied to the piezoelectric element 20. The number of damping waves in the first damping period P_{A3} corresponds to the number of cycles of the damping signal in the first damping period P_{A3} (that is, a quotient obtained by dividing the length of the first damping period P_{A3} by the length of the period of the damping signal). The number of damping waves in the first damping period P_{A3} is a predetermined value (for example, an integer of 2 or more), and is set based on data within a predetermined register in the storage circuit 131. Although it is assumed here that the number of damping waves is “2”, the number of damping waves is not limited (the same is true in the other examples described later). When a length (2/f) corresponding to the two periods of the damping signal has elapsed since time t_{A3} (that is, at time t_{A4}), the first damping period P_{A3} is completed.

In the example of FIG. 12, the state of the drive circuit 111 is switched from the all-off state to the first application state at time t_{A3}, and thus the supply of the damping signal to the piezoelectric element 20 is started. Hence, the phase ϕ of the damping signal in the first damping period P_{A3} is determined by the length of the brake period P_{A2}. When the length of the brake period P_{A2} is represented by T, the phase ϕ of the damping signal is “ϕ=T/(1/f)×2π” in radian notation.

The period from time t_{A4} to time t_{A5} is the second damping period P_{A4}. Although a method can also be adopted in which in the entire second damping period P_{A4}, the damping circuit 140 is continuously connected to the piezoelectric element 20, in the first example, only in a part of the second damping period P_{A4}, the damping circuit 140 is connected to the piezoelectric element 20.

Specifically, the control circuit 130 switches the state of the drive circuit 111 from the second application state to the all-off state at time t_{A4}, and thereafter, at time t_{A12} when only a first predetermined time has elapsed since time t_{A4}, the control circuit 130 switches the state of the drive circuit 111 from the all-off state to the first brake state. The control circuit 130 switches the value of the control signal CNT2 from “0” to “1” at time t_{A13} when only a second predetermined time has elapsed since time t_{A12}. Specifically, the control circuit 130 switches each of the switches 151 and 152 from the off state to the on state at time t_{A13}, and thus the damping circuit 140 is connected to the piezoelectric element 20. In this way, after time t_{A13}, a state where the connection between the damping circuit 140 and the piezoelectric element 20 is interrupted transitions to a state where the damping circuit 140 is connected to the piezoelectric element 20. In the detection unit operation, until time t_{A13} is reached, the value of the control signal CNT2 is assumed to be kept at “0”. Then, the control circuit 130 switches the state of the drive circuit 111 from the first brake state to the all-off state at time t_{A14} when only a third predetermined time has elapsed since time t_{A13}.

Furthermore, the control circuit 130 switches the state of the drive circuit 111 from the all-off state to the first brake state at time t_{A15} after time t_{A14}, and switches the value of the control signal CNT2 from “1” to “0” at time t_{A16} when only a fourth predetermined time has elapsed since time t_{A15}. Specifically, the control circuit 130 switches each of the switches 151 and 152 from the on state to the off state at time t_{A16}, and thus the damping circuit 140 is separated from the piezoelectric element 20. In this way, after time t_{A16}, the state where the damping circuit 140 is connected to the piezoelectric element 20 transitions to the state where the connection between the damping circuit 140 and the piezoelectric element 20 is interrupted. Then, the control circuit 130 switches the state of the drive circuit 111 from the first brake state to the all-off state at time t_{A5} when only a fifth predetermined time has elapsed since time t_{A16}. However, although not shown in the figure in particular, a variation can also be adopted in which in the reception period P_{A5} starting from time t_{A5}, only one of the output terminals DRV1 and DRV2 is fixed to a predetermined potential (for example, the ground potential), and the other is in an open state (the same is true in the other examples described later). Specifically, for example, in the reception period P_{A5}, the transistors M1H and M2H may be off, one of the transistors M2L and M1L may be on and the other may be off.

The voltage value V_{EV} of the envelope signal acquired in the reception circuit 120 is lowered after time t_{A4}. The control circuit 130 may include a comparator (not shown) which compares the voltage value V_{EV} with a predetermined threshold value V_{TH}, and may set time t_{A15} based on the result of the comparison performed by the comparator. Specifically, for example, after the completion of the first damping period P_{A3}, the control circuit 130 may set, to time t_{A15}, a time at which a state where the voltage value V_{EV} is higher than the predetermined threshold value V_{TH} transitions to a state where the voltage value V_{EV} is lower than the predetermined threshold value V_{TH}.

At time t_{A5} or immediately after time t_{A5}, the reverberation is sufficiently reduced. The reception circuit 120 can generate the detection signal based on the voltage signal between the input terminals IN1 and IN2 during the reception period set after time t_{A5}, and the control circuit 130 can perform the distance detection processing and the proximity detection processing described above based on the detection signal during the reception period.

The control circuit 110 may switch the state of the drive circuit 111 to the first brake state immediately after the completion of the first damping period P_{A3}. In other words, the control circuit 110 may switch the state of the drive circuit 111 from the second application state to the first brake state at time t_{A4} (in this case, time t_{A4} and time t_{A12} are interpreted to indicate the same time).

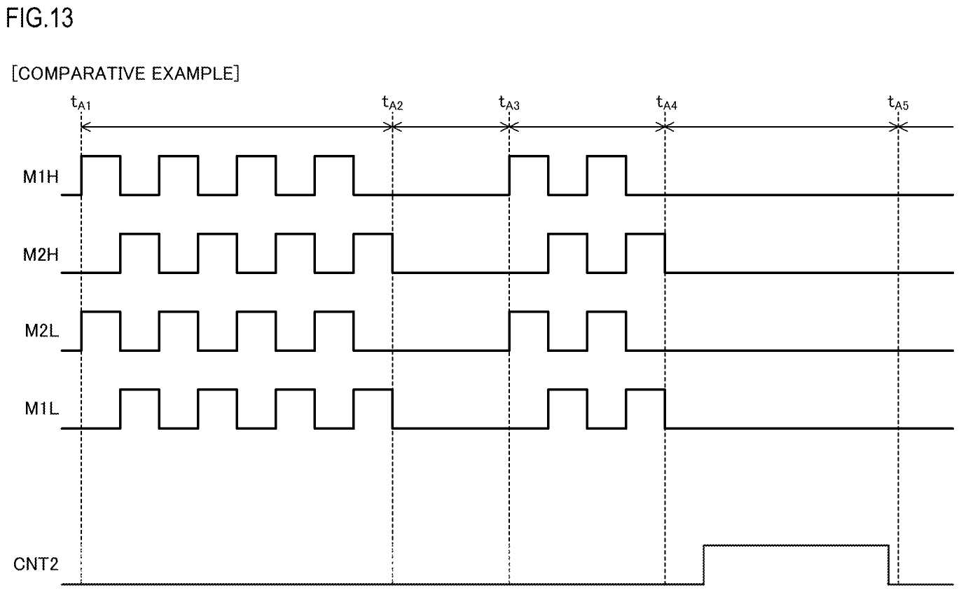

FIG. 13 shows a timing chart in a comparative example which is different from that in the first example. In the comparative example of FIG. 13, between time t_{A2} and time t_{A3} and between time t_{A4} and time t_{A5}, the drive circuit 111 is kept in the all-off state.

By contrast, in the first example, as shown in FIG. 12, after the transmission period P_{A1}, the brake period P_{A2} is provided before the first damping period P_{A3}, and in the brake period P_{A2}, the brake operation of turning on both the transistors M1L and M2L is performed. Hence, unlike the comparative example of FIG. 13, in the brake period P_{A2}, the reverberation energy of the piezoelectric element 20 (that is, the accumulated mechanical energy of the piezoelectric element 20) is discharged to a pattern having the ground potential or is consumed in a current loop via the transistors M1L and M2L and the piezoelectric element 20, with the result that the reverberation time of the piezoelectric element 20 is reduced.

In the first example, after the supply of the drive signal to the piezoelectric element 20 is stopped, the damping signal is supplied to the piezoelectric element 20 by the drive circuit 111, and after the supply of the damping signal is stopped, the damping circuit 140 is connected to the piezoelectric element 20 (this is also true for the comparative example in FIG. 13). In this way, it is also expected that the reverberation is rapidly reduced (that is, the reverberation time can be kept low).

Furthermore, the control circuit 130 in the first example performs damper connection control for connecting, after the supply of the damping signal to the piezoelectric element 20 is stopped, the damping circuit 140 to the piezoelectric element 20 with a specific flow. Specifically, in the damper connection control, the control circuit 130 in the first example starts the brake operation before the damping circuit 140 is connected to the piezoelectric element 20 (time t_{A12}), connects the damping circuit 140 to the piezoelectric element 20 and then stops the brake operation and brings the drive circuit 111 into the all-off state (time t_{A14} via time t_{A13}). If the drive circuit 111 is in the all-off state when the switches 151 and 152 are turned on at time t_{A13} (that is, when the off state is switched to the on state), pulsed noise caused by the turning on of the switches 151 and 152 is applied to the piezoelectric element 20, with the result that the reverberation may be prolonged. The damper connection control is adopted, and thus the potentials of both ends of the piezoelectric element 20 are fixed to the ground potential when the switches 151 and 152 are turned on, with the result that the pulsed noise caused by the turning on of the switches 151 and 152 is absorbed by the pattern having the ground potential. Consequently, the superimposition of the noise on the piezoelectric element 20 is avoided, and thus an increase in the reverberation time caused by the noise is avoided.

Moreover, the control circuit 130 in the first example performs damper disconnection control for disconnecting the damping circuit 140 from the piezoelectric element 20 with a specific flow. Specifically, in the damper disconnection control, the control circuit 130 in the first example starts the brake operation before interrupting the connection between the damping circuit 140 and the piezoelectric element 20 (time t_{A15}), interrupts the connection between the damping circuit 140 and the piezoelectric element 20 and then stops the brake operation (time t_{A5} via time t_{A16}). If the drive circuit 111 is in the all-off state when the switches 151 and 152 are turned off at time t_{A16} (that is, when the on state is switched to the off state), pulsed noise caused by the turning off of the switches 151 and 152 is applied to the piezoelectric element 20, with the result that the reverberation energy which has been reduced may be increased again. The damper disconnection control is adopted, and thus the potentials of both ends of the piezoelectric element 20 are fixed to the ground potential when the switches 151 and 152 are turned off, with the result that the pulsed noise caused by the turning off of the switches 151 and 152 is absorbed by the pattern having the ground potential. Consequently, the superimposition of the noise on the piezoelectric element 20 is avoided, and thus an increase in the reverberation time caused by the noise is avoided.

### Second Example

A second example will be described. The second example is obtained by adding an applied technique to the first example, and for matters which are not specifically described in the second example, the description of the first example is applied to the second example.

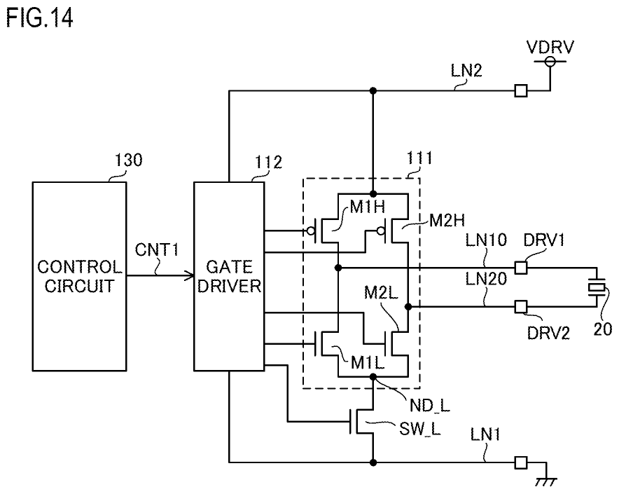

The second example differs from the first example in that a separation switch SW_L shown in FIG. 14 is added to the semiconductor device 10. Specifically, in the first example, the sources of the transistors M1L and M2L are directly connected to the line LN1 whereas in the second example, the separation switch SW_L is inserted between a node ND_L to which the sources of the transistors M1L and M2L are commonly connected and the line LN1. One end of the separation switch SW_L is connected to the node ND_L, and the other end of the separation switch SW_L is connected to the line LN1 to which the ground potential is applied.

Although the separation switch SW_L may be any switching element, here, the separation switch SW_L is assumed to be formed with an n-channel MOSFET, and the n-channel MOSFET serving as the separation switch SW_L is also referred to as the transistor SW_L using a sign of “SW_L”. The turning on of the separation switch SW_L and the turning on of the transistor SW_L are synonymous with each other, and the turning off of the separation switch SW_L and the turning off of the transistor SW_L are synonymous with each other. The drain of the transistor SW_L is connected to the node ND_L, and the source of the transistor SW_L is connected to the line LN1 to which the ground potential is applied. The gate driver 112 controls the gate potentials of the transistors M1H, M1L, M2H, M2L and SW_L according to the control signal CNT1 supplied from the control circuit 130, and thereby individually controls the on/off state of the transistors M1H, M1L, M2H, M2L and SW_L.

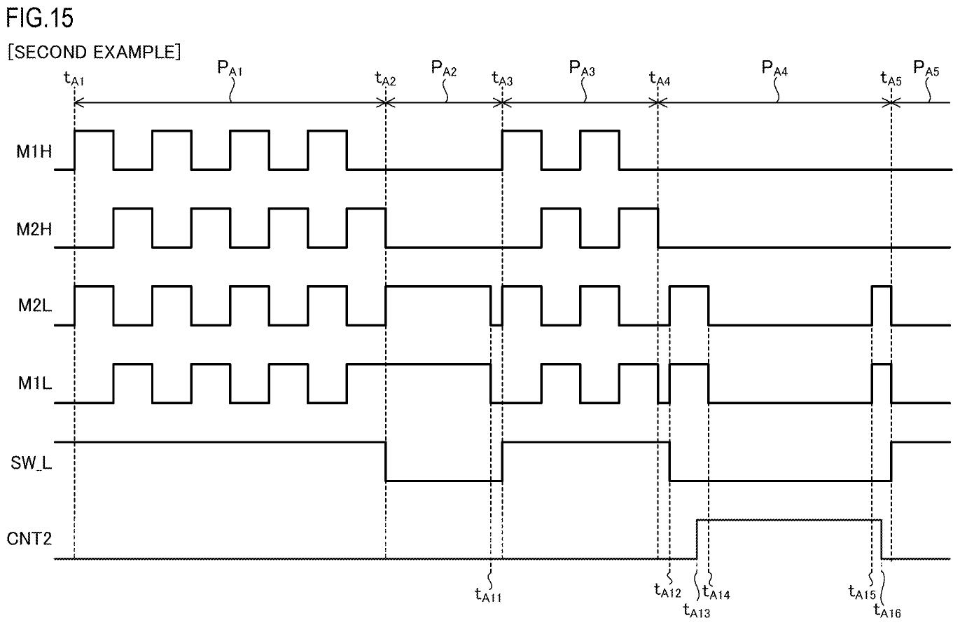

FIG. 15 shows a timing chart of the detection unit operation in the second example. The timing chart of FIG. 15 is obtained by adding the transition of the state of the separation switch SW_L to the timing chart of FIG. 12. Since except for the separation switch SW_L, the details and flow of the detection unit operation are as shown in the first example, in the second example, unless necessary, only the operation of the separation switch SW_L will be described below.

In the detection unit operation, the separation switch SW_L is kept on until time t_{A2} is reached, and is kept off in the brake period P_{A2} between time t_{A2} and time t_{A3}. The separation switch SW_L is kept on in the first damping period P_{A3} between time t_{A3} and time t_{A4} and in the reception period P_{A5} after time t_{A5}. As shown in FIG. 15, the separation switch SW_L is kept on between time t_{A4} and time t_{A12}, and is kept off between time t_{A12} and time t_{A5}. However, the separation switch SW_L may be kept on over the entire second damping period P_{A4} between time t_{A4} and time t_{A5}.

It should be noted that the separation switch SW_L is kept off when the brake operation is performed in the brake period P_{A2} (when both the transistors M1L and M2L are on).

In this way, in the brake period P_{A2}, the current loop via the transistors M1L and M2L separated from the ground pattern and the piezoelectric element 20 is formed, and a current based on the reverberation energy (that is, the accumulated mechanical energy of the piezoelectric element 20) of the piezoelectric element 20 flows through the current loop, with the result that the reverberation energy of the piezoelectric element 20 can be effectively consumed. In the method of the first example, in the brake period P_{A2}, depending on a relationship between the transistors M1L and M2L and the ground pattern and the like, the current based on the reverberant energy of the piezoelectric element 20 may flow into the ground pattern. The flowing of the current thereinto may somewhat degrade the effective reduction of the reverberation, and may also have undesirable effects on other circuits connected to the ground pattern. In the second example, these concerns are eliminated.

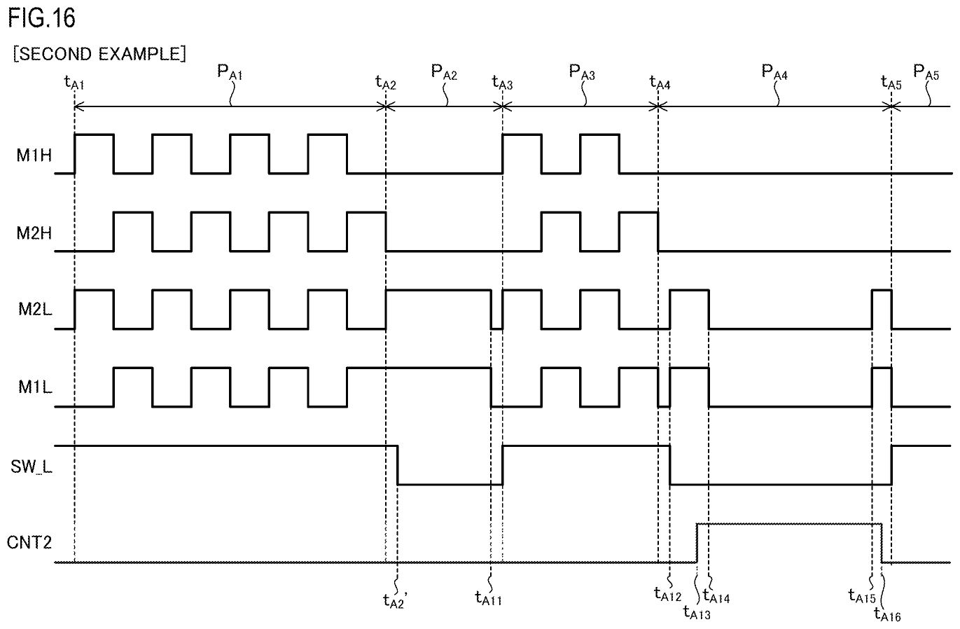

In the example of FIG. 15, the separation switch SW_L is kept off in the entire period (period during which both the transistors M1L and M2L are kept on) during which the brake operation is performed in the brake period P_{A2}. However, in the brake period P_{A2}, the separation switch SW_L may be kept off only in a part of the period during which the brake operation is performed. For example, as shown in FIG. 16, in the detection unit operation, until time t_{A2}′ which is a predetermined minute time after time t_{A2}, the separation switch SW_L may be kept on, and in a period until time t_{A3} after time t_{A2}′ the separation switch SW_L may be kept off. The same is true after time t_{A3}.

The structure of the transistors M1L and M2L may be determined such that an impedance (impedance at the frequency f) between the first end and the second end of the piezoelectric element 20 is equal to the sum of the on-resistances of the transistors M1L and M2L. In this way, the consumption of the reverberation energy of the piezoelectric element 20 caused by the brake operation is maximized, and thus it is possible to rapidly reduce the reverberation.

### Third Example

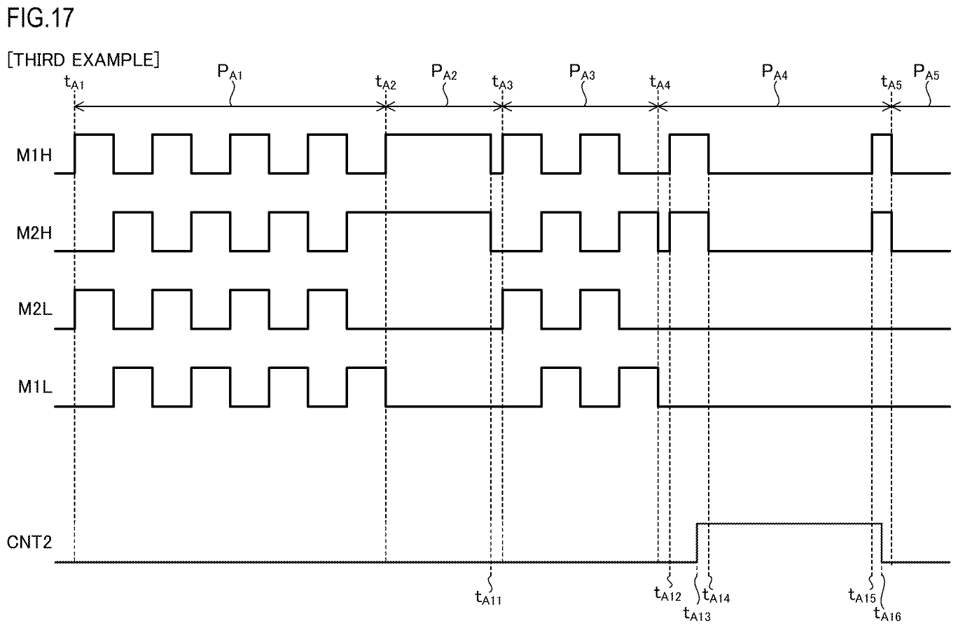

A third example will be described. FIG. 17 shows a timing chart of the detection unit operation in a third example. In the third example, in the brake operation, the drive circuit 111 is set and held in the second brake state (see FIG. 4). The third example is the same as the first example except that the state of the drive circuit 111 in the brake operation is changed from the first brake state to the second brake state based on the first example.

Specifically, in the third example, in all or a part of the brake period P_{A2}, the drive circuit 111 is kept in the second brake state (that is, the transistors M1H and M2H are kept on, and the transistors M1L and M2L are kept off). Hence, within the brake period P_{A2}, the period (period between time t_{A2} and time t_{A11} in the example of FIG. 12) during which the drive circuit 111 is set in the first brake state in the first example is replaced by the period (period between time t_{A2} and time t_{A11} in the example of FIG. 17) during which the drive circuit 111 is set in the second brake state in the third example (this replacement is called a first replacement).

Within the second damping period P_{A4}, the period (a period between time t_{A12} and time t_{A14} and a period between time t_{A15} and time t_{A5} in the example of FIG. 12) during which the drive circuit 111 is set in the first brake state in the first example is replaced by the period (a period between time t_{A12} and time t_{A14} and a period between time t_{A15} and time t_{A5} in the example of FIG. 17) during which the drive circuit 111 is set in the second brake state in the third example (this replacement is called a second replacement). Specifically, the damper connection control and the damper disconnection control described in the first example are also performed in the third example, and in the third example, by the brake operation in the damper connection control and the damper disconnection control, the drive circuit 111 is set and held in the second brake state.

Based on the first example, only one of the first replacement and the second replacement can be performed.

### Fourth Example

A fourth example will be described. The fourth example is obtained by adding an applied technique to the third example, and for matters which are not specifically described in the fourth example, the description of the third example is applied to the fourth example. In the fourth example, the same variation as that from the first example to the second example is made in the third example.

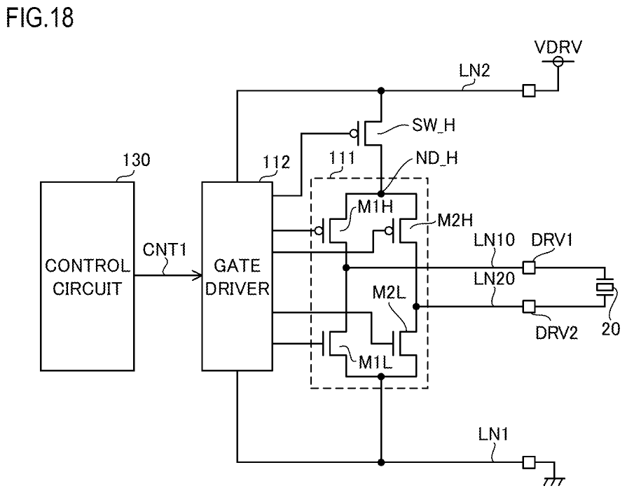

The fourth example differs from the first and third examples in that a separation switch SW_H shown in FIG. 18 is added to the semiconductor device 10. Specifically, in the first and third examples, the sources of the transistors M1H and M2H are directly connected to the line LN2 whereas in the fourth example, the separation switch SW_H is inserted between a node ND_H to which the sources of the transistors M1H and M2H are commonly connected and the line LN2. One end of the separation switch SW_H is connected to the node ND_H, and the other end of the separation switch SW_H is connected to the line LN2 to which the drive power supply voltage VDRV is applied.

Although the separation switch SW_H may be any switching element, here, the separation switch SW_H is assumed to be formed with a p-channel MOSFET, and the p-channel MOSFET serving as the separation switch SW_H is also referred to as the transistor SW_H using a sign of “SW_H”. The turning on of the separation switch SW_H and the turning on of the transistor SW_H are synonymous with each other, and the turning off of the separation switch SW_H and the turning off of the transistor SW_H are synonymous with each other. The drain of the transistor SW_H is connected to the node ND_H, and the source of the transistor SW_H is connected to the line LN2 to which the drive power supply voltage VDRV is applied. The gate driver 112 controls the gate potentials of the transistors M1H, M1L, M2H, M2L and SW_H according to the control signal CNT1 supplied from the control circuit 130, and thereby individually controls the on/off state of the transistors M1H, M1L, M2H, M2L and SW_H.

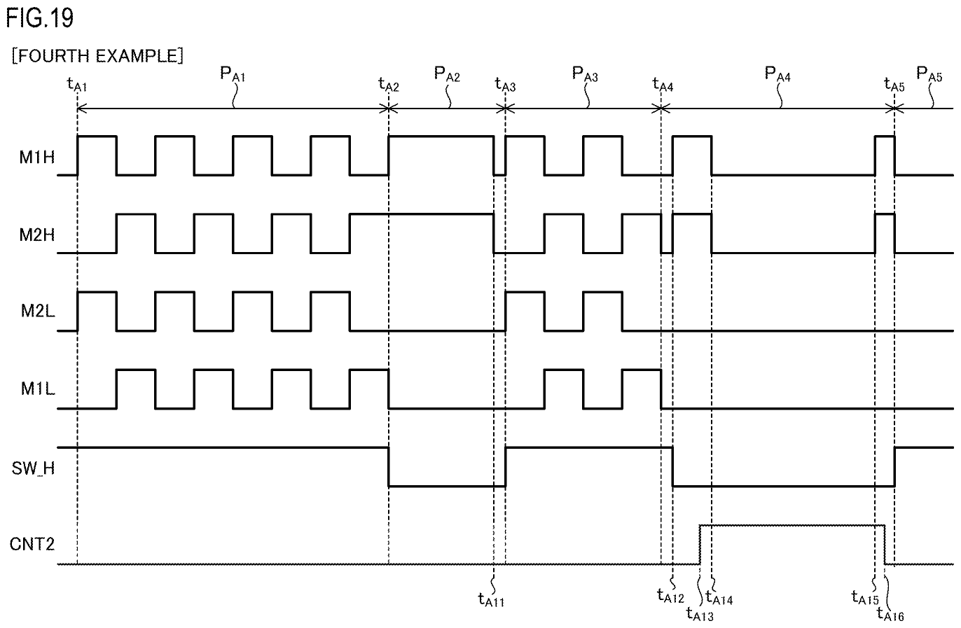

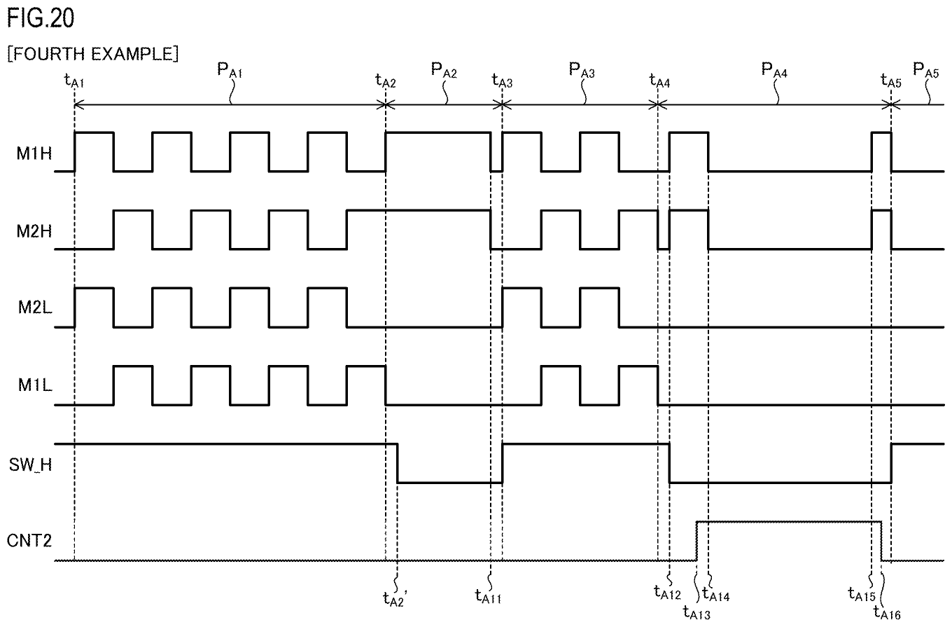

FIG. 19 shows a timing chart of the detection unit operation in the fourth example. The state control (on/off control) of the separation switch SW_H in the fourth example is the same as the state control (on/off control) of the separation switch SW_L in the second example, and the description of the state control of the separation switch SW_L in the second example is applied to the fourth example. In this application, the separation switch SW_L in the second example is only replaced by the separation switch SW_H in the fourth example. As in the variation from FIG. 15 to FIG. 16 described in the second example, a variation from FIG. 19 to FIG. 20 can be made. Hence, in the fourth example, in all or a part of the period (period during which the drive circuit 111 is set and held in the second brake state) during which the brake operation is performed in the brake period P_{A2}, the separation switch SW_H is kept off. In the transmission period P_{A1}, the first damping period P_{A3} and the reception period P_{A5}, the separation switch SW_H is kept on. Although in the example of FIG. 19, the separation switch SW_H is kept off between time t_{A12} and time t_{A5}, the separation switch SW_H may be held on over the entire second damping period P_{A4}.

In the fourth example, the structure of the transistors M1H and M2H may be determined such that the impedance (impedance at the frequency f) between the first end and the second end of the piezoelectric element 20 is equal to the sum of the on-resistances of the transistors M1H and M2H. In this way, the consumption of the reverberation energy of the piezoelectric element 20 caused by the brake operation is maximized, and thus it is possible to rapidly reduce the reverberation.

### Fifth Example

A fifth example will be described. In the fifth example, application techniques, variation techniques, supplementary items and the like for the techniques described above will be described.

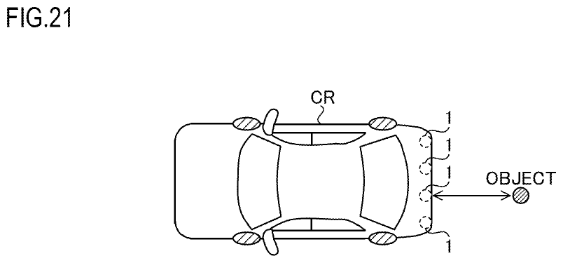

The ultrasonic sensor 1 can be installed in any device. For example, as shown in FIG. 21, one or more ultrasonic sensors 1 may be installed in a vehicle CR such as an automobile. In the example of FIG. 21, four ultrasonic sensors 1 are installed in a back portion of the body of the vehicle CR, the ultrasonic sensors 1 are used and thus the distance detection processing and the proximity detection processing can be performed on an object (an example of the object to be detected OBJ in FIG. 1) located on the side of the back portion of the vehicle CR. Here, the upper block 2 may be an ECU (Electronic Control Unit) which is installed in the vehicle CR.

The type of channel of the FET (Field Effect Transistor) shown in each embodiment is an example, and the configuration of a circuit including the FET can be changed such that the n-channel FET is changed to the p-channel FET or the p-channel FET is changed to the n-channel FET.

Any of the transistors described above may be any type of transistor as long as there is no inconvenience. For example, any of the transistors described above as a MOSFET can be replaced with a junction FET, an IGBT (Insulated Gate Bipolar Transistor) or a bipolar transistor as long as there is no inconvenience. Any of the transistors includes a first electrode, a second electrode and a control electrode. In the FET, one of the first and second electrodes is the drain, the other is the source and the control electrode is the gate. In the IGBT, one of the first and second electrodes is the collector, the other is the emitter and the control electrode is the gate. In the bipolar transistor which does not belong to the IGBT, one of the first and second electrodes is the collector, the other is the emitter and the control electrode is the base.

The embodiment of the present disclosure can be variously changed as necessary within the scope of the technical idea indicated in the scope of claims. The embodiment described above is merely an example of the embodiment of the present disclosure, and the meanings of the present disclosure and the terms of the constituent elements are not limited to those described in the above embodiment. Specific values shown in the above description are merely examples, and can naturally be changed to various values.

### ADDITIONAL REMARKS

Additional remarks are provided for the present disclosure in which specific configuration examples are shown in the embodiment described above.

A semiconductor device (10; see FIG. 3) according to an aspect of the present disclosure includes: a drive circuit (111) which can supply a drive signal in an ultrasonic band to a piezoelectric element (20), and can supply, after the supply of the drive signal is stopped, a damping signal having a phase different from a phase of the drive signal to the piezoelectric element; and a control circuit (130) which can control the drive circuit, the drive circuit includes a full bridge circuit which is provided between a first line (LN1) and a second line (LN2) to which a potential higher than the first line is to be applied, and uses the full bridge circuit to be able to supply the drive signal and the damping signal to the piezoelectric element based on a potential difference between the first line and the second line, the full bridge circuit includes a series circuit of a first switch (M1H) provided on the side of the second line and a second switch (M1L) provided on the side of the first line and a series circuit of a third switch (M2H) provided on the side of the second line and a fourth switch (M2L) provided on the side of the first line, and can respectively connect a connection node between the first switch and the second switch and a connection node between the third switch and the fourth switch to a first end and a second end of the piezoelectric element, the control circuit can cause, after the supply of the drive signal to the piezoelectric element is stopped, the drive circuit to perform a brake operation before the damping signal is supplied to the piezoelectric element (see FIG. 12 or 17) and in the brake operation, the first switch and the third switch are turned off and the second switch and the fourth switch are turned on or the first switch and the third switch are turned on and the second switch and the fourth switch are turned off (first configuration).

By the brake operation described above, the reverberation energy of the piezoelectric element based on the drive signal (that is, the accumulated mechanical energy of the piezoelectric element) is discharged to the pattern of the first or second line or is consumed in a current loop via the second and fourth switches and the piezoelectric element or a current loop via the first and third switches and the piezoelectric element, with the result that the reverberation time of the piezoelectric element is reduced.

Preferably, the semiconductor device according to the first configuration (see FIGS. 14 to 16) further includes: a separation switch (SW_L) which is inserted between a connection node between the second switch and the fourth switch and the first line, and the control circuit keeps the separation switch on in a period during which the drive signal is supplied to the piezoelectric element and in a period during which the damping signal is supplied to the piezoelectric element, and keeps the separation switch off in at least a part of a period during which the first switch and the third switch are turned off and the second switch and the fourth switch are turned on by the brake operation (second configuration).

The separation switch is kept off in the brake operation, and thus the current loop via the second and fourth switches separated from the first line and the piezoelectric element is formed, and a current based on the reverberation energy (that is, the accumulated mechanical energy of the piezoelectric element) of the piezoelectric element flows through the current loop, with the result that the reverberation energy of the piezoelectric element can be effectively consumed.

Preferably, the semiconductor device according to the first configuration (see FIGS. 18 to 20) further includes: a separation switch (SW_H) which is inserted between a connection node between the first switch and the third switch and the second line, and the control circuit keeps the separation switch on in a period during which the drive signal is supplied to the piezoelectric element and in a period during which the damping signal is supplied to the piezoelectric element, and keeps the separation switch off in at least a part of a period during which the first switch and the third switch are turned on and the second switch and the fourth switch are turned off by the brake operation (third configuration).

The separation switch is kept off in the brake operation, and thus the current loop via the first and third switches separated from the second line and the piezoelectric element is formed, and a current based on the reverberation energy (that is, the accumulated mechanical energy of the piezoelectric element) of the piezoelectric element flows through the current loop, with the result that the reverberation energy of the piezoelectric element can be effectively consumed.

Preferably, the semiconductor device according to any one of the first to third configurations (see FIGS. 3 and 12) further includes: a damping circuit (140) which includes a resistive load (141) and an inductive load (142), and the control circuit causes, after the supply of the drive signal to the piezoelectric element is stopped, the drive circuit to supply the damping signal to the piezoelectric element through the brake operation, and thereafter can connect the damping circuit to the piezoelectric element (fourth configuration).

After the supply of the drive signal to the piezoelectric element is stopped, the damping signal having a phase different from the phase of the drive signal is supplied to the piezoelectric element, and thus it is possible to reduce the reverberation of the piezoelectric element. Although the damping signal is effective for reducing the reverberation in a region where the amplitude of the reverberation (the amplitude of the piezoelectric element caused by the reverberation) is high, as the amplitude of the reverberation is lowered, the damping signal itself may serve as a factor for new reverberation. On the other hand, the resistive load or the inductive load is connected to the piezoelectric element after the supply of the drive signal is stopped, thus the reverberation is reduced through the absorption of the mechanical energy of the piezoelectric element. Here, the inventor has found this time that the resistive load or the inductive load has a relatively high reverberation reduction effect when the amplitude of the reverberation is small whereas the reverberation reduction effect is relatively low when the amplitude of the reverberation is large due to a voltage restriction for the circuit or the like. Based on the findings described above, the fourth configuration is adopted, and thus it is possible to rapidly reduce the reverberation (that is, the reverberation time can be kept low).

Preferably, in the semiconductor device according to the fourth configuration (see, for example, between time t_{A12} and time t_{A14} in FIG. 12), the control circuit can perform damper connection control after the supply of the damping signal to the piezoelectric element is stopped (after time t_{A4}), starts the brake operation in the damper connection control before the damping circuit is connected to the piezoelectric element, stops the brake operation after the damping circuit is connected to the piezoelectric element and turns off all the first to fourth switches (fifth configuration).

In the damper connection control, the superimposition of noise on the piezoelectric element which can be caused when an interrupted state between the damping circuit and the piezoelectric element is switched to a connected state is avoided. Consequently, an increase in the reverberation time caused by the noise is avoided.

Preferably, in the semiconductor device according to the fifth configuration (see, for example, between time t_{A15} and time t_{A5} in FIG. 12), the control circuit can perform, after the supply of the damping signal to the piezoelectric element is stopped (after time t_{A4}), damper disconnection control after connecting the damping circuit and the piezoelectric element by the damper connection control (after time t_{A13}), starts the brake operation before the damping circuit is interrupted from the piezoelectric element in the damper disconnection control and stops the brake operation after the damping circuit is interrupted from the piezoelectric element (sixth configuration).

In the damper disconnection control, the superimposition of noise on the piezoelectric element which can be caused when the connected state between the damping circuit and the piezoelectric element is switched to the interrupted state is avoided. Consequently, an increase in the reverberation time caused by the noise is avoided.

Preferably, in the semiconductor device according to any one of the fourth to sixth configurations, in the damping circuit, the resistive load and the inductive load are connected in parallel (seventh configuration).

An ultrasonic sensor according to an aspect of the present disclosure includes: the semiconductor device according to any one of the first to seventh configurations; and a piezoelectric element which is connected to the semiconductor device (eight configuration).

1. A semiconductor device comprising:
a drive circuit configured to be capable of supplying a drive signal in an ultrasonic band to a piezoelectric element, and be capable of supplying, after the supply of the drive signal is stopped, a damping signal having a phase different from a phase of the drive signal to the piezoelectric element; and
a control circuit configured to be capable of controlling the drive circuit,
wherein the drive circuit includes a full bridge circuit which is provided between a first line and a second line to which a potential higher than the first line is to be applied, and uses the full bridge circuit to be able to supply the drive signal and the damping signal to the piezoelectric element based on a potential difference between the first line and the second line,
the full bridge circuit includes a series circuit of a first switch provided on a side of the second line and a second switch provided on a side of the first line and a series circuit of a third switch provided on the side of the second line and a fourth switch provided on the side of the first line, and can respectively connect a connection node between the first switch and the second switch and a connection node between the third switch and the fourth switch to a first end and a second end of the piezoelectric element,
the control circuit can cause, after the supply of the drive signal to the piezoelectric element is stopped, the drive circuit to perform a brake operation before the damping signal is supplied to the piezoelectric element and
in the brake operation, the first switch and the third switch are turned off and the second switch and the fourth switch are turned on or the first switch and the third switch are turned on and the second switch and the fourth switch are turned off.

2. The semiconductor device according to claim 1 further comprising:
a separation switch which is inserted between a connection node between the second switch and the fourth switch and the first line,
wherein the control circuit keeps the separation switch on in a period during which the drive signal is supplied to the piezoelectric element and in a period during which the damping signal is supplied to the piezoelectric element, and keeps the separation switch off in at least a part of a period during which the first switch and the third switch are turned off and the second switch and the fourth switch are turned on by the brake operation.

3. The semiconductor device according to claim 1 further comprising:
a separation switch which is inserted between a connection node between the first switch and the third switch and the second line,
wherein the control circuit keeps the separation switch on in a period during which the drive signal is supplied to the piezoelectric element and in a period during which the damping signal is supplied to the piezoelectric element, and keeps the separation switch off in at least a part of a period during which the first switch and the third switch are turned on and the second switch and the fourth switch are turned off by the brake operation.

4. The semiconductor device according to claim 1 further comprising:
a damping circuit which includes a resistive load and an inductive load,
wherein the control circuit causes, after the supply of the drive signal to the piezoelectric element is stopped, the drive circuit to supply the damping signal to the piezoelectric element through the brake operation, and thereafter can connect the damping circuit to the piezoelectric element.

5. The semiconductor device according to claim 4,
wherein the control circuit can perform damper connection control after the supply of the damping signal to the piezoelectric element is stopped, starts the brake operation in the damper connection control before the damping circuit is connected to the piezoelectric element, stops the brake operation after the damping circuit is connected to the piezoelectric element and turns off all the first to fourth switches.

6. The semiconductor device according to claim 5,
wherein the control circuit can perform, after the supply of the damping signal to the piezoelectric element is stopped, damper disconnection control after connecting the damping circuit and the piezoelectric element by the damper connection control, starts the brake operation before the damping circuit is interrupted from the piezoelectric element in the damper disconnection control and stops the brake operation after the damping circuit is interrupted from the piezoelectric element.

7. The semiconductor device according to claim 4,
wherein in the damping circuit, the resistive load and the inductive load are connected in parallel.

8. An ultrasonic sensor comprising:
the semiconductor device according to claim 1; and
a piezoelectric element which is connected to the semiconductor device.
